(19) United States
(12) Patent Application Publication
(10) Pub. No.: US 2009/0121273 A1
(43) Pub. Date: May 14, 2009

(54) Low-voltage memory having flexible gate charging element

(76) Inventors: Tsu-Jae King, Fremont, CA (US); Gang Liu, Fremont, CA (US); Min She, Fremont, CA (US)

Correspondence Address: JOHN P. O'BANION;O'BANION & RITCHEY LLP, 400 CAPITOL MALL SUITE 1550, SACRAMENTO, CA, 95814, US

(21) Appl. No.: 11/664,018

(22) PCT Filed: Sep. 22, 2005
(86) PCT No.: PCT/US05/34206

§ 371 Date: Dec. 11, 2008

Related U.S. Application Data
(60) Provisional application No. 60/614,706, filed on Sep. 29, 2004.

(51) Int. Cl. H01L 29/68; H01L 29/788

(52) U.S. Cl. 257/316; 257/E29.17; 257/E29.3

(57) ABSTRACT

In a non-volatile semiconductor memory device including a source region separated from a drain region by a channel region and with an electrically floating gate electrode spaced from and overlying the channel region, a flexible member is spaced from the floating gate and capable of being flexed towards the floating gate for depositing or removing electrical charge on the floating gate in response to a voltage potential between the flexible member and the channel region. In one embodiment, the flexible member comprises a contact gate electrode. In another embodiment, only a single gate electrode is employed without a separate floating gate.

### BACKGROUND OF THE INVENTION

This invention relates to semiconductor memory devices, and more particularly the invention relates to a floating gate flash memory device in which charge on a floating gate between a channel region and a control gate of a transistor controls conduction voltage of the transistor.

Aggressive scaling of semiconductor memory cells and the dramatic increase in the memory array size demand high density/low cost flash memory. Floating gate flash memory is a popular semiconductor memory device. It is available from many IC manufacturers. It is used in personal computers, cellular phones, digital cameras, smart-media, networks, automotive, global positioning systems and so on. The device structure of an industry standard floating gate memory is shown in FIG. 1.

A heavily doped poly-silicon floating gate 10 is sandwiched between the tunnel oxide 12 and inter-poly silicon oxide 14. A control gate 16 is voltage biased to control conduction in a channel 18 in a doped well 20 between a source 22 and a drain 24.

The floating gate flash memory is programmed by either hot electron injection, where hot electrons with large kinetic energy injecting into the floating gate near the drain side, or by Fowler-Nordheim tunneling, where cold electrons tunnel through the tunnel oxide along the whole channel. Currently, commercial flash memory devices use tunnel oxide thicker than 8 nm to guarantee 10 years retention time, which in turn results in high programming voltage and slow programming speed.

Table 1 shows the 2002 International Technology Roadmap for Semiconductor flash memory. The operation voltage and the tunnel oxide will not scale at all in the coming five technology generations. And the scalability below 65 nm is still questionable.

TABLE 1
The tunnel oxide and operation voltage scaling predicted by the
2002 International Technology Roadmap for Semiconductors.

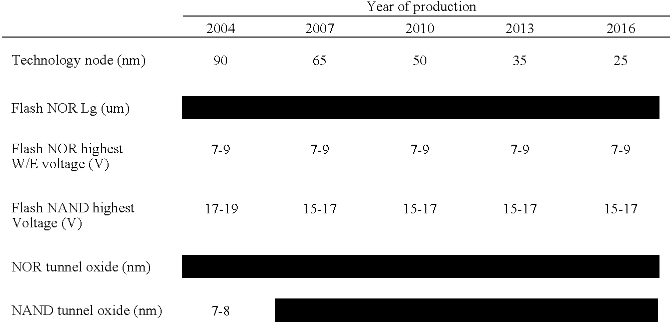

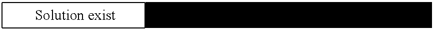

In the conventional floating gate flash memory, the tunnel oxide limits the operation voltage scaling. The present invention overcomes this limitation.

### SUMMARY OF THE INVENTION

The present invention provides improved cell programming which allows low voltage operation. In an embodiment of the memory cell, a thin sacrificial layer between the control gate and the floating gate will be released during processing, whereby the control gate can move towards and away from the floating gate freely. When appropriate bias is applied, the control gate can be pulled in and touch the floating gate.

In one embodiment, the floating gate is charged with electrons front the control gate when the control gate is biased with a negative voltage and a doped p-well is biased with a positive voltage. Once the floating gate is charged such that the potential difference between floating gate and control gate is less than the pull-in voltage, the control gate will be restored back up. The injected electrons will be stored in the floating gate which causes V_{T}, channel threshold voltage, to increase. The writing “1” into the cell is done. Since electrons are injected from the control gate into the floating gate by contacting the floating gate instead of through the tunnel oxide, low voltage operation can be achieved with fast programming/erasing speed. By controlling the bias on the control gate and the p-well, one can precisely control the exact amount of charge injected into the floating gate, hence multi-bit operation with single memory cell is obtained.

The invention and object and features thereof will be more readily apparent from the following detailed description and appended claims when taken with the drawings.

### BRIEF DESCRIPTION OF THE DRAWINGS

FIG. 1 is a section view of a conventional floating gate flash memory cell.

FIGS. 2a-2c are a top view and two section views of a flash memory cell in accordance with one embodiment of the invention.

FIG. 3 is a section view of the memory cell of FIG. 2 during programming of the floating gate.

FIGS. 4a, 4b are a top view and section view of the memory cell of FIG. 2 and illustrate dimensions thereof for one embodiment using 0.13 micron technology.

FIG. 5 is a graph of Paschen's Curve (Pressure vs. Breakdown voltage) for one embodiment of the invention.

FIG. 6 is a top view of a 4×4 NAND memory array in accordance with an embodiment of the invention.

FIGS. 7a-7k are section views illustrating the fabrication of a memory cell in accordance with one embodiment of the invention.

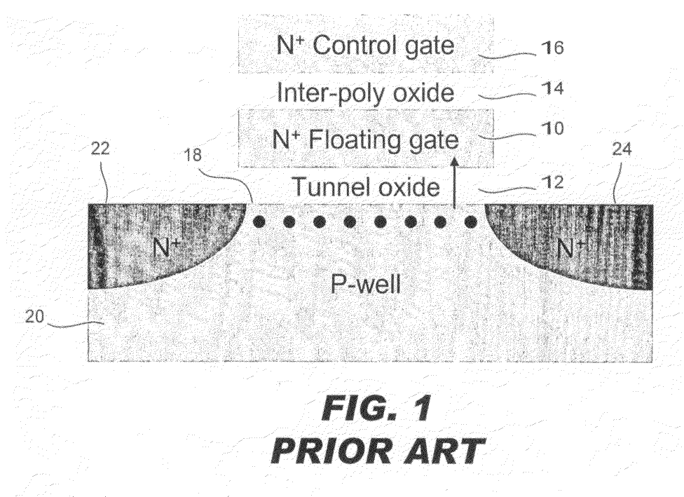

### DETAILED DESCRIPTION OF THE PREFERRED EMBODIMENTS

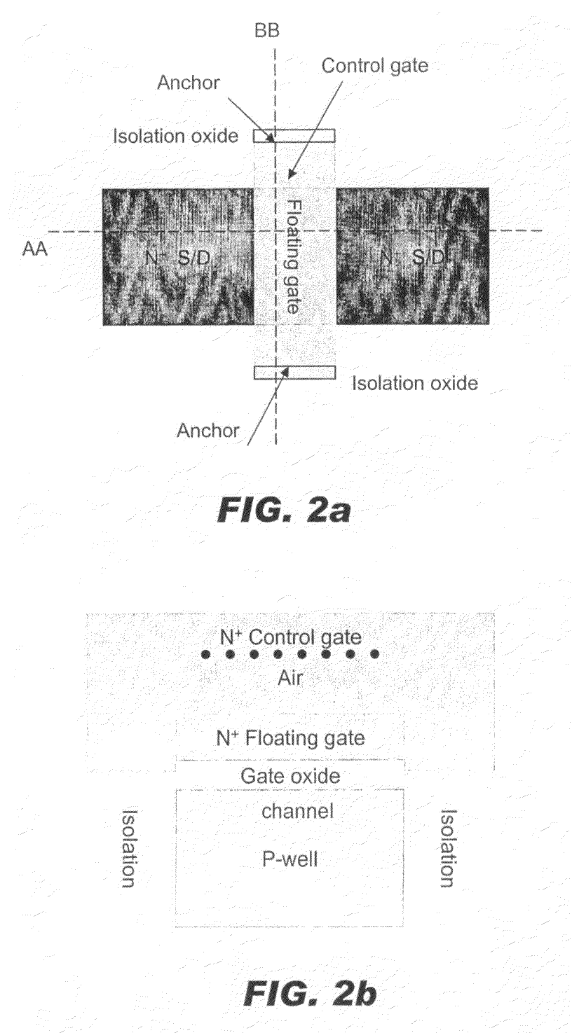

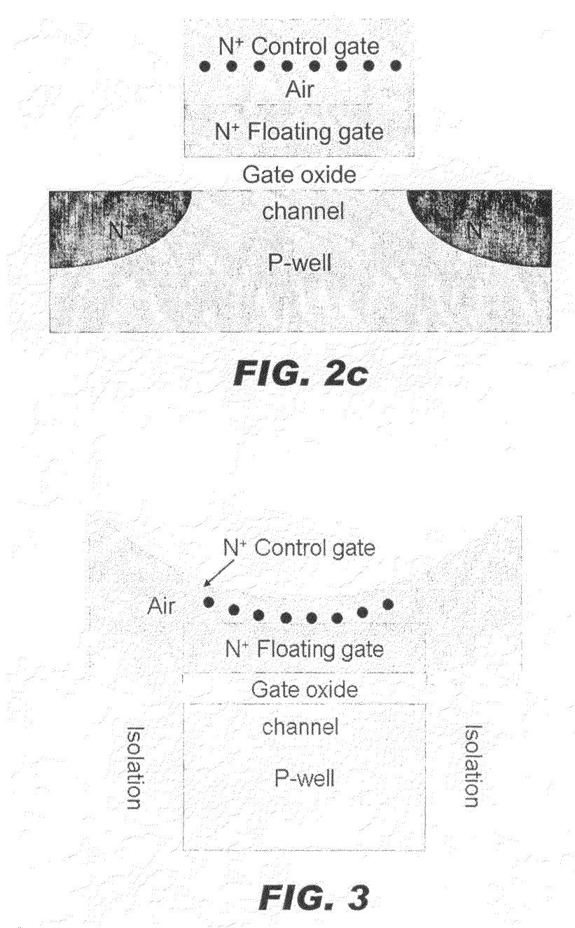

FIGS. 2a, 2b and 2c are a top view and two section views along different axes (AA and BB of FIG. 2a) of a flash memory cell in accordance with one embodiment of the invention.

As shown in FIG. 2(b), the inter-poly oxide in the conventional flash memory is replaced with air gap by releasing the sacrificial between the control gate and the floating gate. The two ends of the control gate are anchored on the isolation area. The movement of the control gate is controlled by proper voltage biasing applied as shown in FIG. 3, which is a cross section view along BB line. The control gate bends toward the floating gate and touch it as long as the voltage drop across them exceeds a certain pull-in voltage.

The potential of the floating gate is determined by the coupling of the floating gate to the source, drain, well, and control gate. The coupling ratio of the floating gate to the source, drain, well, and control gate can be adjusted by properly designing the gate oxide thickness and the air gap height. The floating gate is more coupled to the source/drain/well instead of to the control gate in a properly designed memory cell. The coupling coefficients are defined as:

$$\begin{matrix}{α}_{S} = \frac{{C}_{S}}{{C}_{S} + {C}_{D} + {C}_{B} + {C}_{G}} & ( 1 ) \\ {α}_{D} = \frac{{C}_{D}}{{C}_{S} + {C}_{D} + {C}_{B} + {C}_{G}} & ( 2 ) \\ {α}_{B} = \frac{{C}_{B}}{{C}_{S} + {C}_{D} + {C}_{B} + {C}_{G}} & ( 3 ) \\ {α}_{G} = \frac{{C}_{G}}{{C}_{S} + {C}_{D} + {C}_{B} + {C}_{G}} & ( 4 )\end{matrix}$$

Here C_{S}, C_{D}, C_{B} and C_{G} are the capacitance of the floating gate to the source, drain, well and control gate, respectively, while α_{S}, α_{D}, α_{B} and α_{G} are the corresponding coupling ratio coefficients respectively. A set of typical coupling ratio coefficients for conventional flash memory are given as follows: α_{S}=0.1, α_{D}=0.1, α_{B}=0.6 and α_{G}=0.2. The floating gate potential can be expressed as:

$${V}_{FG} = {α}_{S} * {V}_{S} + {α}_{D} * {V}_{D} + {α}_{B} * {V}_{B} + {α}_{G} * {V}_{G} + \frac{Q}{{C}_{S} + {C}_{D} + {C}_{B} + {C}_{G}} \qquad ( 5 )$$

Here Q is the charge stored in the floating gate. For simplicity, Q is assumed to be 0 at the beginning of the programming/erasing pulse. The voltage difference between the floating gate and the control gate is the programming/erasing voltage. It is expressed as:

$$\begin{matrix}{V}_{prog / erase} = {V}_{CG} - {V}_{FG} \\ = ( 1 - {α}_{G} ) * {V}_{G} - \\ {α}_{S} * {V}_{S} - {α}_{D} * {V}_{D} - {α}_{B} * {V}_{B} - \\ \frac{Q}{{C}_{S} + {C}_{D} + {C}_{B} + {C}_{G}}\end{matrix} \qquad ( 6 )$$

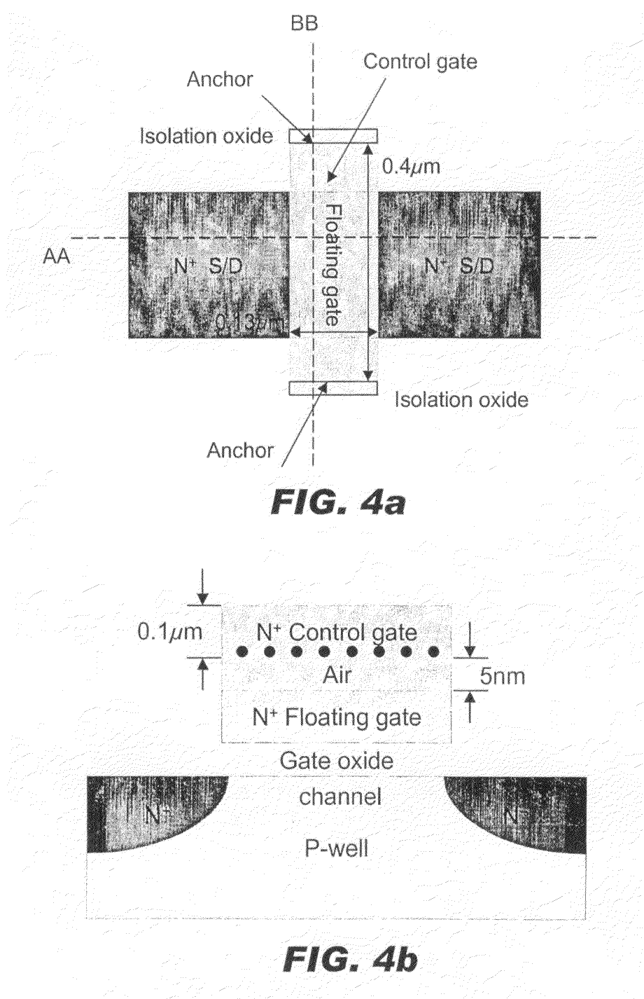

Please note that in the proposed memory cell, the floating gate is more coupled to the well comparing to the conventional flash memory so we can control the potential on the floating gate more effectively by adjusting the well bias. Another benefit is that small floating gate can be used, so there is less coupling between adjacent floating gates in the memory array, while tall floating gate is required to achieve a large coupling to the control gate in conventional flash memory. With equation (6), we then can estimate the needed voltage in order to make the proposed memory cell functional. FIG. 4 shows the dimension of a single Micro-Electro-Mechanical flash memory Cell in 0.13 μm technology.

For a double-supported beam, spring constant is shown below

$$k = \frac{4 {EWH}^{3}}{{L}^{3}} \qquad ( 7 )$$

Here, E is Young's Modulus (1.6 GPa for poly-Si), W is Channel Length, L is cell width, H is the thickness of the control gate.

Pull-in voltage of voltage-controlled parallel-plate electrostatic actuator is given as:

$${V}_{PI} = \sqrt{\frac{8 {kg}^{3}}{27 ɛ WL}} = \sqrt{\frac{32 {EH}^{3} {g}^{3}}{27 ɛ {L}^{4}}} \qquad ( 8 )$$

Here, g is gap width, and ε is permittivity of vacuum.

Plugging in the numbers as shown in the embodiment of FIG. 4, the required pull-in voltage is 1.02V, much lower than the state-of-the-art flash memory operation voltage. As scaling continues, we could scale H, L, g with the same factor such that operating voltage scales the same factor as well. So the proposed memory is very scaling friendly.

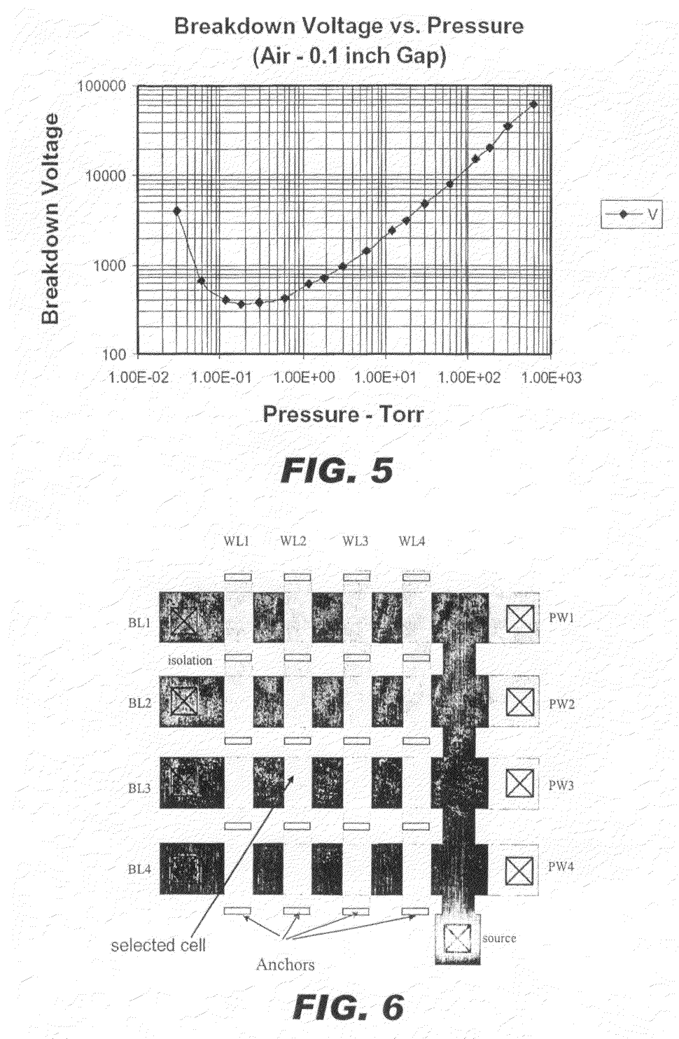

The factor that will affect the retention time of the proposed memory cell is discharge in the air gap. In the 19^{th} century, Paschen, a German scientist, conducted experiments to determine electrical arc characteristics as ambient pressure changed. At higher pressure, the breakdown voltage is a function of the gas pressure and the width of the gap. And Townsend Avalanche is the dominant mechanism for breakdown. FIG. 5 is shown the “Paschen Curve” for air, two flat parallel copper electrodes for pressures between 30 mTorr and 760 Torr. It is predicted that as the pressure is reduced below a few torr (as shown in the diagram below) the curve of breakdown voltage versus pressure reaches a minimum, and then, as pressure is further reduced, rises steeply again.

However, Paschen curve did not predict the breakdown accurately for the narrow gaps as often used in Micro-Electro-Mechanical systems. In narrow gaps, there are few ionizable molecules which could be approximately treated as in vacuum. Field emission will be the main breakdown mechanism and is estimated to be 1V/nm for vacuum. The embodiment of this invention can stand up to 5 V. And the required voltage for proper operation is 2 V. Hence, discharging will not happen in the proposed memory cell. In operations, there are no electrons tunneling happening through gate oxide. Thus, the quality of the gate oxide is conserved.

Thus, superior retention time performance is obtained in the embodiment of this invention.

Array operation will now be described with reference to the top view of a NAND memory array is shown in FIG. 6. All the cells along each bit line share one P-well. The P-well corresponding to the bit line “BL*” are labeled as “PW*”. Detailed operation of programming, reading, erasing will be given below. To be concise, programming is done by injecting electrons into the floating gate as an example. The operation could also be done by removing electrons from the floating gate by flipping the bias polarity.

Write operation (programming “1”)—In FIG. 6, only the selected cell is programmed while the other cells are prevented from being programmed. The word line “WL2” and bit line “PW3” is biased at −1.0V and 1.0V, respectively, while other word lines and P-well are grounded. All of the bit lines are floated. The potential of the source and drain junction of the cell (WL2, BL3) will follow the potential of its well and reaches 0.3V for the worse case, assuming that a turn on voltage of a PN junction is 0.7V. Programming voltages V_{prog}=V_{CG}−V_{FG} (potential difference between the control gate and the floating gate) for each cell are:

V_{prog}=−1.46V on the selected cell (WL2, PW3).

Along the word line “WL1”, “WL3” and “WM4”, V_{prog}=0V on the cell that shares any one of the bit line “BL1”, “BL2” and “BL4”.

Along the bit line “BL3”, V_{prog}=−0.66V on the cell that shares any one of the word line “WL1”, “WL3” and “WL4”.

Along the word line “WL2”, V_{prog}=−0.8V for every cell except the selected cell.

Since the pull-in voltage is calculated to be 1.02V, it is obvious that only the selected cell will be programmed, while all of the other cells will be immune to “soft programming”.

(b) Write operation (programming “0”)—In this operation, the bias are adjusted such that there is no pull-in happening. The floating gate remains in the previous state of no electrons, corresponding to a “0” state.

(c) Read operation—During read operation, just like conventional NAND flash memory, both select transistors are enabled, causing a conditional discharge of the bit line.

(d) Erase operation—During the erasing cycle, every word line is biased at 2.0V, every P-well is biased at 1V and the bit lines are floated. According to equation (6), the erasing voltage for each cell will be approximately 1.5V depending on the amount of electrons stored in the floating gate. Then the whole block is erased simultaneously. During erasure, all the cell modules will be programmed to become depletion devices. Individual cell erasure is possible with proper biasing.

(e) Multi-bit operation—As described in the previous section, the proposed memory cell could perform multi-bit operation. This is done by adjusting the potential difference of the control gate and the floating gate through appropriate biasing of the control gate and the well. So we could control the amount of the electrons injected into the floating gate to achieve multi-bit operation.

5) Comparison with other memory technology—Table 2 illustrates a Performance Comparison among volatile memory (DRAM and SRAM), nonvolatile memory (Flash, FRAM, MRAM and phase change memory) devices and the embodiment of this invention. Among the other nonvolatile memory technologies, flash memory is the only memory compatible with the current CMOS process flow. The observation of Table 2 is that the embodiment of this invention inherits almost all the advantages of the conventional flash memory technology. Meanwhile, it solves the problems that conventional flash memory technology faces today, such as high voltage, low speed and scaling issue. Comparing to other novel memory technology, the embodiment of this invention does not involve new materials, has good compatibility with CMOS, low power consumption, and demonstrates high performance.

TABLE 2
Performance Comparison among volatile memory (DRAM and SRAM), nonvolatile memory (Flash,
FRAM, MRAM and phase change memory) devices and the embodiment of this invention.

| | Memory type | | | | | | | |
|---|---|---|---|---|---|---|---|---|
| | | | | | | | Phase | |
| | | | | Flash- | | | change | |
| | DRAM | SRAM | Flash-NOR | NAND | FRAM | MRAM | memory | MEMory |
| Cell size factor | 6~12 | 90~150 | 8~10 | 4 | 18 | 10~20 | 5~8 | 8 |
| (F²) | | | | | | | | |
| Largest array | | | 256 | 2000 | 64 | 1 | 4 | |
| built (Mb) | | | | | | | | |
| Volatile/Non- | Volatile | Volatile | NV | NV | NV | NV | NV | NV |
| volatile | | | | | | | | |
| Endurance | ∞/∞ | ∞/∞ | 10⁶/∞ | 10⁶/∞ | 10¹²/10¹² | 10¹⁴/∞ | 10¹²/∞ | 10¹⁴/∞ |
| write/read | | | | | | | | |
| Read | Destructive | Partially- | Non- | Non- | Destructive | Non- | Non- | Non- |
| | | destructive | destructive | destructive | | destructive | destructive | destructive |
| Read/Program | ~1 | ~1 | 2/10 | 2/18 | 1.5/1.5 | 3.3/3.3 | 0.4/1 | 1/2 |
| voltage (V) | | | | | | | | |
| Program/Erase/ | 50/50/8 | 8/8/8 | 1 us/1-100 ms | 1 ms/1- | 80/80/80 | 30/30/30 | 50/50/50 | 50/50/50 |
| Read speed, ns | | | (block)/60 ns | 100 ms/60 ns | | | | |
| Direct over- | Yes | Yes | No | No | Yes | Yes | Yes | Yes |
| write | | | | | | | | |
| Bit/byte | Yes | Yes | Yes | Block erase | Yes | Yes | Yes | Yes |
| Write/Erase | | | | | | | | |
| Read dynamic | 100-200 mV | 100-200 mV | Delta | Delta | 100-200 mV | 20-40% R | 10X- | Delta |
| range (margin) | | | current | current | | | 100XR | current |
| Programming | Medium | Medium | High | Low | Medium | Medium | Low | Low |
| energy | | | | | | | | |
| Transistors | Low | High | High | High | Low | High | High | High |
| | performance | performance | voltage | voltage | performance | performance | performance | Performance |
| CMOS logic | Bad | Good | Ok, but Hi | Ok, but Hi | Ok, but Hi | | Good | Good |
| compatibility | | | V needed | V needed | V needed | | | |
| New materials | Yes | No | No | No | Yes | Yes | Yes | No |
| Scalability | Capacitor | 6 T (4 T | Tunnel | Tunnel | Polarizable | Current | Lithography | Lithography |
| limit | | possible) | oxide/HV | oxide/HV | capacitor | density | | |
| Multi-bit | No | No | Yes | Yes | No | No | No | Yes |
| storage | | | | | | | | |
| 3D potential | No | No | Possible | Possible | ? | ? | No | Possible |
| SER | Yes | Yes | No | No | Yes | No | No | No |
| susceptibility | | | | | | | | |
| Relative cost | Low | High | Medium | Medium | High | ? | Low | Low |
| per bit | | | | | | | | |
| Extra mask | | | 6-8 | | 2 | 4 | 3-4 | 1~2 |
| needed for | | | | | | | | |
| embedded | | | | | | | | |
| memory | | | | | | | | |
| In production | Yes | yes | Yes | Yes | Yes | 2004 | N/A | N/A |

Among the other nonvolatile memory technologies, flash memory is the only memory compatible with the current CMOS process flow.

In an alternative embodiment, a simpler memory cell design does not include a floating gate electrode. The moveable element mostly comprises a single gate electrode. The cell can have a thin (<1 nm) coating layer; the resistance between the source and drain will depend on the position of the gate electrode. For example, the single-gate memory device could be an n-channel MOS transistor with a high-work-function gate electrode (e.g., heavily p-type doped poly-Si). When the gate electrode is close to (or in contact) with the gate insulator overlying the channel region, the threshold voltage of the transistor is high, so that it is off (i.e., high resistance between the source and drain). When the gate electrode is suspended away from the gate insulator, the threshold voltage of the transistor is low (due to the classic “short channel effect”), so that it is on (i.e., low resistance between the source and drain).

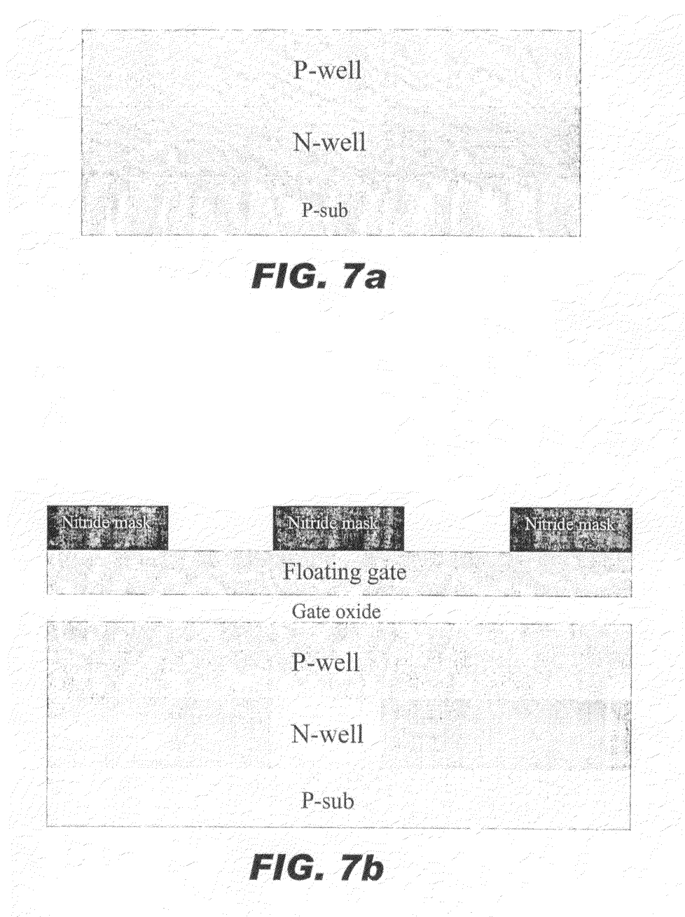

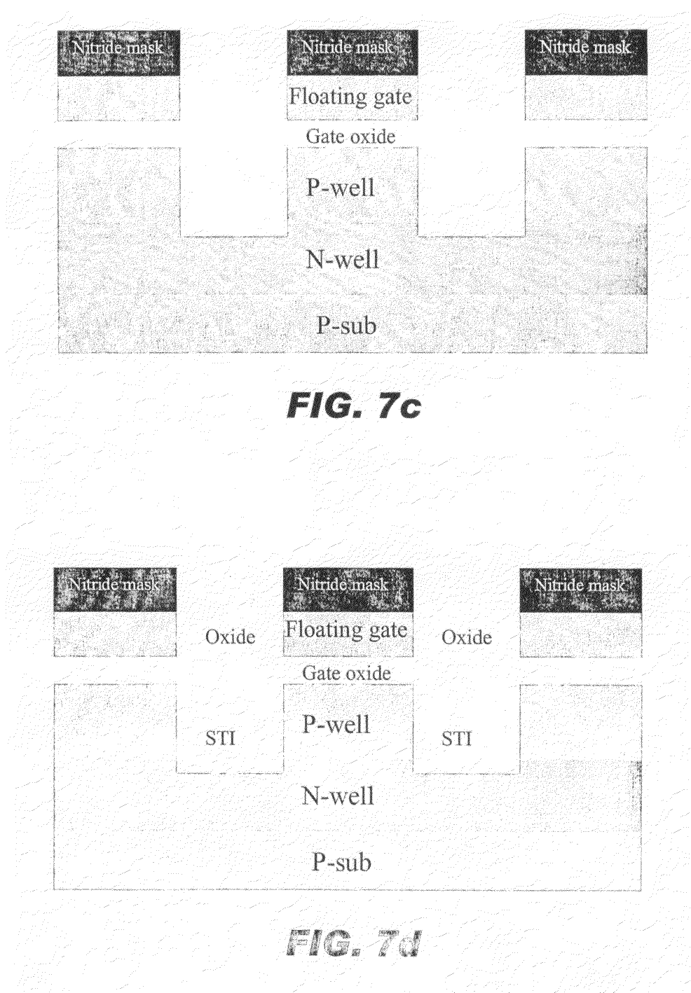

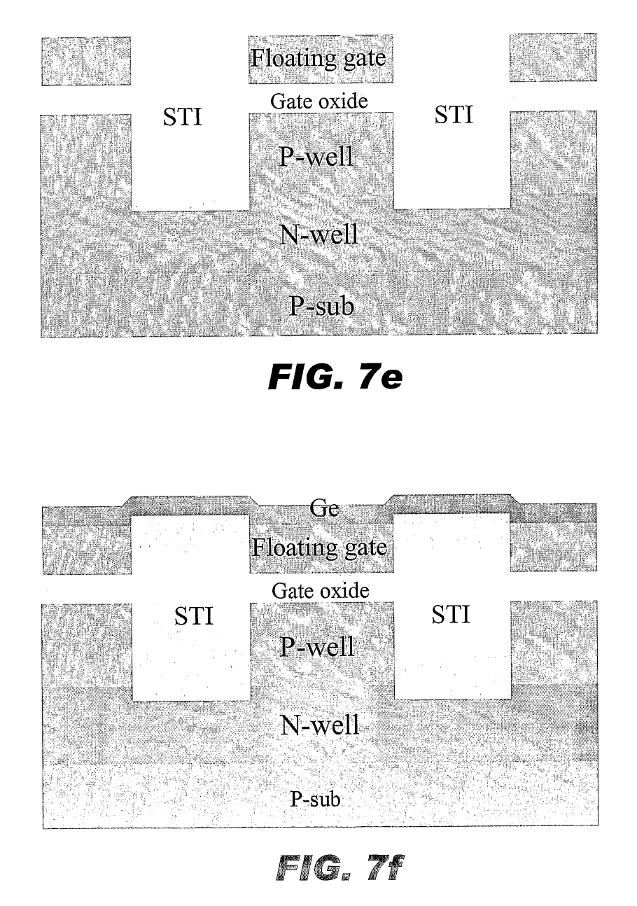

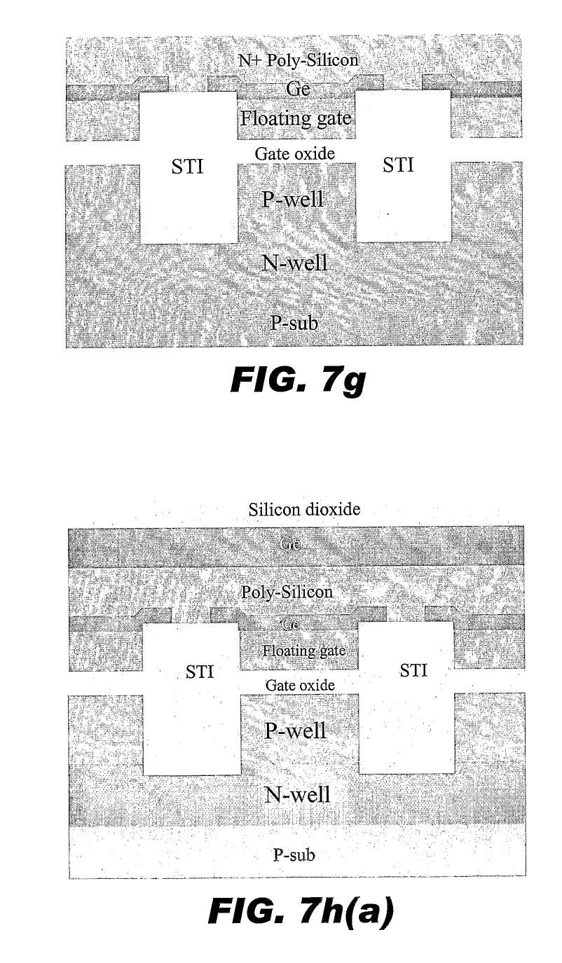

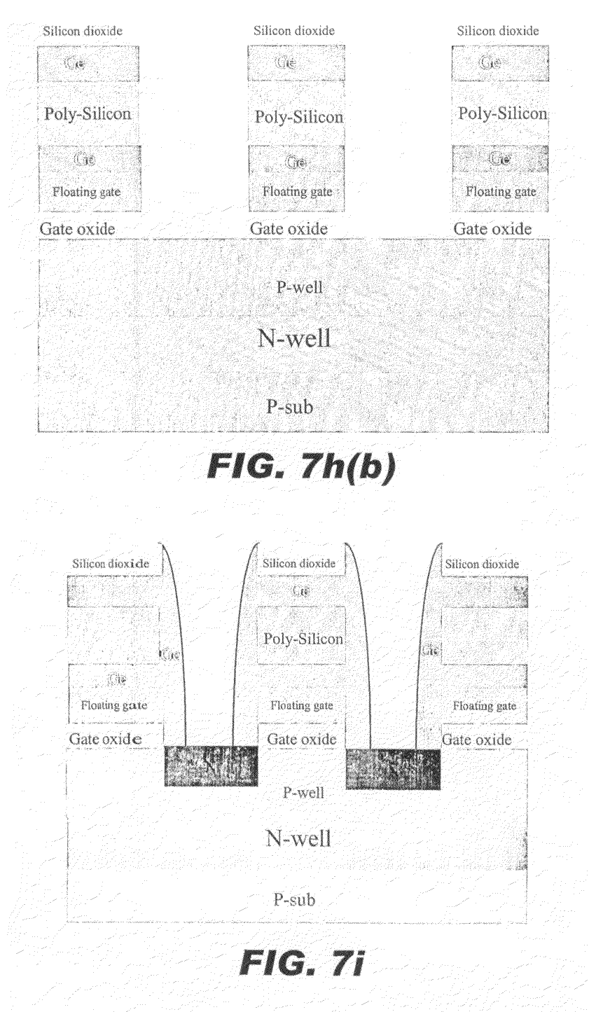

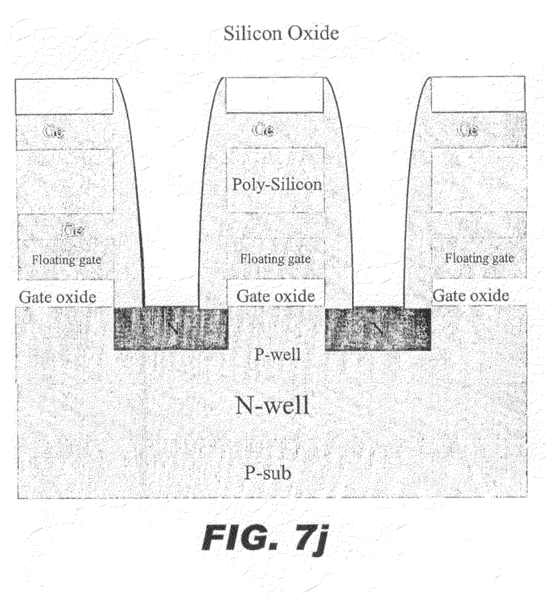

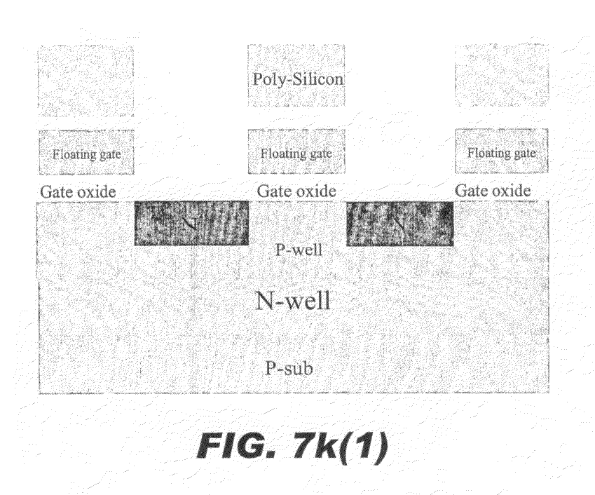

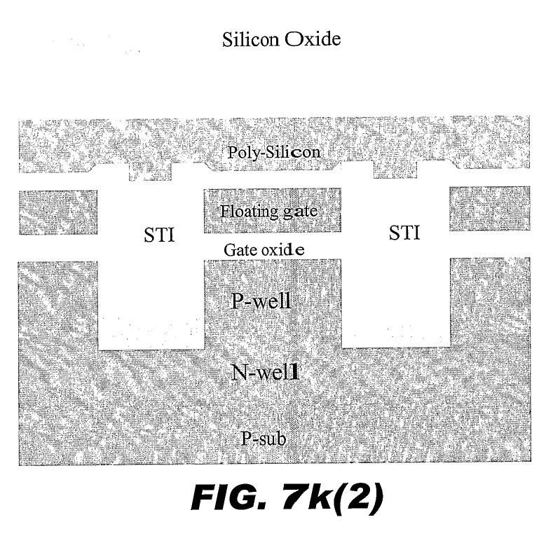

The process flow to fabricate the MEMory is demonstrated in the following steps illustrated in the cross sections of FIGS. 7a-7h:

a) The starting material is a p-type doped silicon substrate. After N-well and P-well formation, channel implantation is done to adjust the threshold voltage of the memory cells, as shown in FIG. 7a.

A 5 nm gate oxide is grown thermally, followed by deposition of a 20 nm N+ in-situ doped amorphous silicon film layer as the floating gate. Then a 50 nm nitride is deposited and patterned as a hard mask. The nitride width defines the channel width of the memory cells.

c) A dry etching method etches holes through the floating gate, gate oxide, P-well and portion of the N-well.

d) Silicon Dioxide is deposited on top of the wafer. Chemical Mechanical Polishing method (CMP) polishes the oxide to form shallow trench isolation (STI).

(e) Nitride hard mask is selectively etched.

(f) 5 nm germanium film (sacrificial layer) deposited.

g) After germanium film is patterned, a 100 nm N+ in-situ doped Poly-silicon layer is deposited. (FIG. 7g).

(h-a) A 50 nm germanium film is deposited on top of the Poly-silicon layer, followed by deposition of 100 nm silicon dioxide hard mask. Then word lines are patterned. (FIG. 7h-a). The cross-section along the bit line direction is shown in FIG. 7(h-b).

(h-b) Cross-section view along bit line direction after patterning and etching of word lines in shown in FIG. 7h(b).

(i) A thin layer of germanium film (−15 nm) is deposited and is etched back to form germanium spacers. The source/drain of the memory cells are implanted (FIG. 7i).

(Note: from this step on, only a cross-section along bit line direction is shown, except that cross-section along word line direction will be shown in the Poly-silicon release step.)

(j) Then a thick silicon oxide layer is deposited as the passivation layer. (FIG. 7j).

(k) After the germanium film is selectively etched by hot water, the poly-silicon word lines are released. The cross-section along the bit line direction (FIG. 7k1) and the cross-section along the word line direction (FIG. 7k2) are shown. Vent holes that are used to release the control gate are sealed after release. Then a standard backend process finishes the memory array fabrication.

The invention provides a low-voltage, high speed, superior retention time, and high density Micro-Electro-Mechanical flash memory. Since the electrons are injected into the floating gate via a direct current from the control gate, the novel flash cell offers program/erase speed as fast as nanoseconds as well as low voltage operation. The memory core density is comparable to the state-of-the-art flash memory, while the peripheral circuit can be aggressively scaled to achieve high density memory chip. Additionally, the scalability of the proposed memory is very good which offers a solution beyond the 65 nm technology node.

While the invention has been described with reference to specific embodiments, the description is illustrative of the invention and is not to be construed as limiting the invention. Various modifications and applications may occur to those skilled in the art without departing from the spirit and scope of the invention as defined by the appended claims.

What is claimed is:

1. In a non-volatile semiconductor memory device including a source region separated from a drain region by a channel region and with an electrically floating gate electrode spaced from and overlying the channel region, a flexible member spaced from the floating gate and capable of being flexed towards the floating gate for depositing or removing electrical charge on the floating gate in response to a voltage potential between the flexible member and the channel region.

2. The flexible member of claim 1 wherein the flexible member has a stable position spaced from the floating gate electrode.

3. The flexible member of claim 1 wherein the flexible member makes physical contact with the floating gate electrode while electrical charge is being transferred to or from the floating gate electrode.

4. The flexible member as defined by claim 1, claim 2, or claim 3 wherein the memory cell further includes a control gate electrode.

5. The flexible member as defined by claim 1, claim 2, or claim 3 wherein the flexible member substantially comprises a control gate electrode.

6. A non-volatile memory cell comprising:
a) a semiconductor body having a source region and a drain region in separate surface locations in the semiconductor body,
b) a channel region between the source region and the drain region,
c) an electrically floating gate electrode located above and spaced from the channel region, the floating gate configured to accept charge for programming the memory cell, and
d) a control gate electrode located above and spaced from the floating gate electrode, the control gate electrode being capable of flexing towards the floating gate electrode for depositing or removing electrical charge on the floating gate in response to a voltage potential between the control gate and the channel region.

7. The non-volatile memory cell of claim 6 wherein the control gate electrode has a stable position spaced from the floating gate electrode.

8. The non-volatile memory cell of claim 6 wherein the control gate electrode physically contacts the floating gate electrode for depositing or removing electrical charge on the floating gate electrode.

9. In a semiconductor non-volatile memory device including a source region separated from a drain region by a channel region, and an electrically insulating film overlying the channel region, a flexible member spaced from the electrically insulating film and capable of being flexed towards the electrically insulating film for modifying the electrical resistance between the source region and the drain region, wherein the flexible member substantially comprises a single gate electrode.

10. The flexible member of claim 9 wherein the flexible member has a first stable position spaced a first distance from the electrically insulating film, and a second stable position spaced a second distance from the electrically insulating film.

11. The flexible member of claim 9 wherein the flexible member has a first stable position spaced from the electrically insulating film, and a second stable position in contact with the electrically insulating film.

12. A non-volatile memory cell comprising:
a) a semiconductor body having a source region and a drain region in separate surface locations in the semiconductor body,
b) a channel region between the source region and the drain region,
c) an electrically insulating film overlying the channel region,
d) a single gate electrode located above and spaced from the electrically insulating film, the single gate electrode being capable of flexing towards the electrically insulating film for modifying the electrical resistance between the source region and the drain region.

13. The non-volatile memory cell of claim 12 wherein the single gate electrode has a stable position spaced from the electrically insulating film.

14. The non-volatile memory cell of claim 12 wherein the single gate electrode has a first stable position spaced a first distance from the electrically insulating film, and a second stable position spaced a second distance from the electrically insulating film.

15. The non-volatile memory cell of claim 12 wherein the single gate electrode has a first stable position spaced from the electrically insulating film, and a second stable position in contact with the electrically insulating film.
